(19) United States
(12) Patent Application Publication
(10) Pub. No.: US 2022/0310497 A1
(43) Pub. Date: Sep. 29, 2022

(54) Partially Staggered Ball Array for Reduced Noise Injection

(71) Applicant: Dialog Semiconductor (UK) Limited, London (GB)

(72) Inventors: Nicola Bramante, Swindon (GB); Rupert Howes, Stroud (GB)

(21) Appl. No.: 17/211,991

(22) Filed: Mar. 25, 2021

(51) Int. Cl. H01L 23/498; H01L 23/64; H01L 23/50

(52) U.S. Cl. CPC H01L 23/49816; H01L 23/49838; H01L 23/645; H01L 23/50

(57) ABSTRACT

A package having reduced injected noise into balls carrying sensitive signals is described. An array of solder balls is mounted on a substrate wherein the solder balls provide package output. Solder balls adjacent to a noise-sensitive solder ball package output are shifted by one-half the pitch of the array of solder balls to equalize mutual parasitic inductance around the noise-sensitive solder ball package output.

### (1) Technical Field This disclosure is related to ball grid array (BGA) packages, and more particularly, to reduce injected noise into balls in BGA packages.

### (2) Background

BGA (ball grid array) packages are used for many applications. Package mutual parasitics may come mainly from balls rather than from the substrate itself, especially for flip chip BGA (FCBGA) packages based on copper pillar technology, and contribute to injecting noise into balls carrying sensitive signals (e.g., but not limited to, feedback nodes in switching converters or other circuits). Any noisy current into an inductance creates an undesired change in voltage. Depopulating balls from the array helps with reducing mutual capacitance but not inductance. Staggering of all the package balls (interstitial BGAs) may be done to ease substrate routing, but not for the purpose of reducing localized noise injection from the package. Some packages might use localized staggering just on package corners to reduce mechanical stress on corners and improve reliability. Other packages might also use localized staggering to isolate radio frequency (RF) blocks as a whole, i.e. on the package there would be an RF island with its own bailout and layout. Some packages might use additional ground balls to reduce noise injection from the package.

U.S. Patents 9,490,227 (Dedic et al), 7,831,949 (Tokunga et al), and 6,791,177 (Miller et al) and U.S. Patent Applications 2019/0304899 (Park et al) all discuss noise-sensitive circuitry in BGA packages.

### SUMMARY

It is the primary objective of the present disclosure to reduce injected noise into balls carrying sensitive signals in a BGA package.

It is a further objective of the present disclosure to reduce injected noise into balls carrying sensitive signals in a BGA package (e.g., but not limited to, feedback nodes in switching converters or other circuits) without the need of extra ground balls.

Yet another objective is to reduce injected noise into balls carrying sensitive signals in a BGA package by staggering the layout locally of those balls carrying sensitive signals.

In accordance with the objectives of the present disclosure, a BGA package having reduced injected noise into balls carrying sensitive signals is achieved. An array of solder balls is mounted on a substrate wherein the solder balls provide package output. Solder balls adjacent to a noise-sensitive solder ball package output are shifted to equalize mutual parasitic inductance around the noise-sensitive solder ball package output.

Also in accordance with the objectives of the present disclosure, a method for fabricating a BGA package having reduced injected noise into balls carrying sensitive signals is achieved. A plurality of solder balls is provided on a substrate wherein the solder balls provide package output. An array layout of the plurality of solder balls is designed wherein for each solder ball that is a noise-sensitive package output, adjacent balls to the noise-sensitive solder ball are shifted so as to equalize mutual parasitic inductance around the noise-sensitive solder ball.

Also in accordance with the objectives of the present disclosure, a package having reduced injected noise into balls carrying sensitive signals is achieved. An array of solder balls is mounted on a substrate wherein the solder balls provide package output. Solder balls adjacent to a noise-sensitive solder ball package output are shifted by one-half the pitch of the array of solder balls to equalize mutual parasitic inductance around the noise-sensitive solder ball package output.

### BRIEF DESCRIPTION OF THE DRAWINGS

In the accompanying drawings forming a material part of this description, there is shown:

FIG. 1 is a circuit diagram of an example of a circuit that could utilize the package in the present disclosure.

FIG. 2 is a bottom view of a Ball Grid Array (BGA) package of the example circuit of FIG. 1.

FIG. 3 is a bottom view of a Ball Grid Array (BGA) package of the example circuit of FIG. 1 having the localized staggered ball layout of the present disclosure.

FIG. 4 is a cross-sectional representation of a BGA package of the present disclosure cut along the line 4A-4A′ of FIG. 3.

### DETAILED DESCRIPTION

The present disclosure solves the problem of non-equal mutual parasitic inductance for noise-sensitive signals in a Ball Grid Array (BGA) package by partial staggering of balls, that is, staggering applied locally to specific balls which carry sensitive signals. The partial staggering achieves equal mutual inductance for the sensitive ball of interest, relative to the neighboring balls which carry switching signals. This is achieved without the need for extra balls and can be applied to any ball carrying sensitive signals.

FIG. 1 is an example of a circuit for which a BGA package of the present disclosure would be desirable. FIG. 1 is a diagram of a typical DC-DC switching converter. Comms/GPIOs 100 are input and output signals to and from Interface Circuitry 102. AVDD 104 is a power source for the Driving Circuitry 106, which controls the Power Stage 108. The Power Stage 108 is connected to power supply voltages PVDD 110 and PGND 112, where PVDD is typically a positive voltage, and PGND is connected to ground or a very low voltage. The Power Stage 108 drives one or more inductors at its output via signals LXA 114, LXB 116,..., LXN 118, the output of which (that is, the opposite side(s) of the inductor(s)) is the voltage or voltages provided to a Point of Load 120 and controlled by the switching converter. The output voltage is fed back to the switching converter via feedback signals FBP 122 and FBN 124, which are used to control the loop of the switching converter output voltage(s).

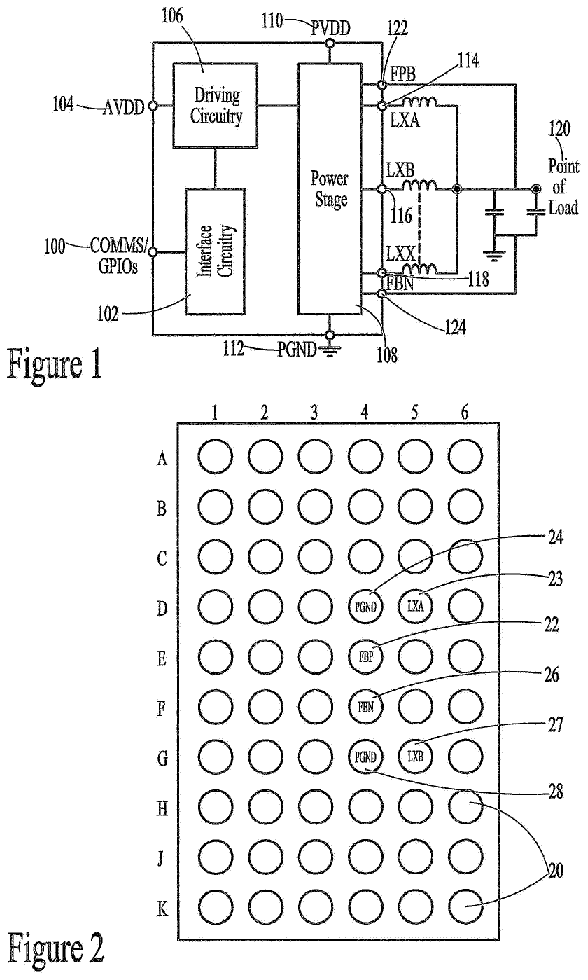

FIG. 2 shows the bottom side of a BGA array that might have been fabricated to implement the switching converter of Fig. 1. For example, solder balls 20 are laid out in an array of rows A-K and columns 1-6. There may be more or fewer rows and/or columns in the array.

For example, rows E and F are GPIOs and Comms related balls. Rows A to D and G to K are power stages so duplication of PVDD, PGND and LXX balls. The arrangement / pin out depends on the number of phases used for the switching converter. Depending on the number of phases needed, one can have more or fewer power stage balls. Circuitry other than switching converters can utilize this package arrangement so unlabeled balls could be other signals too.

Depending on the ball assignment, the noise sensitive signals (FBP 22 and FBN 26 in this example) might get assigned in the center of the array. This is usually the case for multi-phase switching converters where the overall solution size imposes constraints in terms of form factor and size. The center of the array could also have other balls carrying noise sensitive signals other than FBP and FBN. Other circuits than switching converters could also be implemented.

Using the example shown in FIGS. 1 and 2, the mutual inductance between FBP 22 and LXA 23 is different than the mutual inductance between FBP 22 and PGND 24. Mutual inductance is affected by the distances between the pairs of balls and the polarity of the neighboring balls, for example, whether or not PGND is close by. Likewise, for the quadrant containing FBN 26, the mutual inductance between FBN 26 and LXB 27 is different than the mutual inductance between FBN 26 and PGND 28.

In copper pillar based technology (FCBGA), the major contributor to the mutual inductance is the ball. Reducing the diameter of the balls would reduce their parasitic inductance contribution, but in high current applications a maximum current per ball needs to be maintained to achieve the required performance, especially for high power applications, so reducing ball diameter is not a viable option.

The relative difference in mutual inductance from FBP/FBN to the neighbor balls causes an undesired voltage (noise) in the FBP-FBN signal which is amplified by the control loop of the switching converter, for example, leading to unwanted oscillations and/or instability of the switching converter.

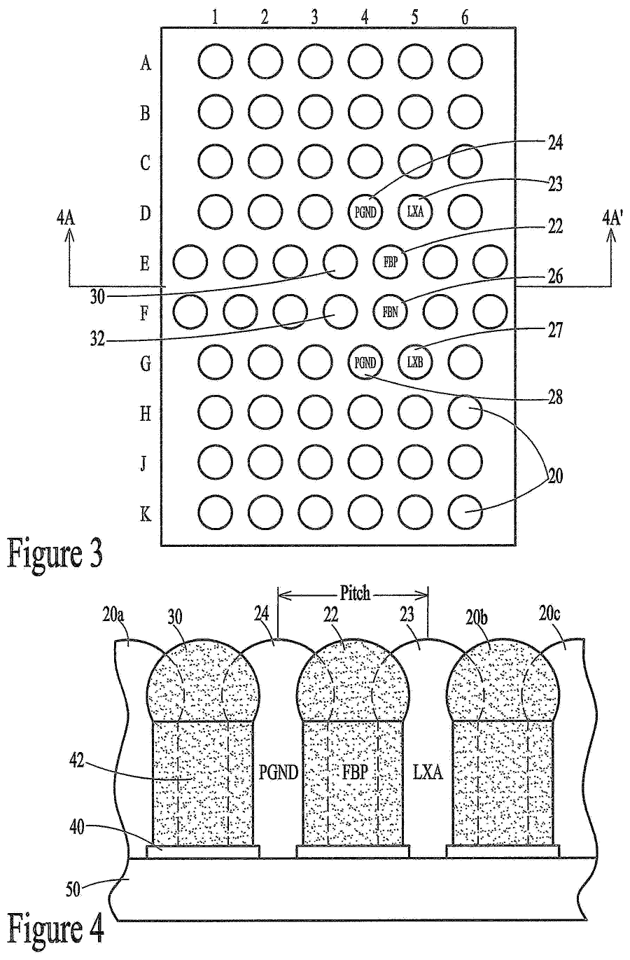

FIG. 3 illustrates the bottom view of the BGA according to the present disclosure. The balls in rows E and F have been moved by half a pitch to the right for the right quadrant and half a pitch to the left for the left quadrant, creating a partially staggered array. With this arrangement, the mutual inductance between FBP 22 and LXA 23 is the same as the mutual inductance between FBP 22 and PGND 24. Likewise, in the quadrant where FBN 26 is, mutual inductance between FBN 26 and LXB 27 is the same as the mutual inductance between FBN 26 and PGND 28. This has been confirmed by extracting the mutual parasitics at the package level.

The movement of balls also creates room for two additional balls 30 and 32, which can be assigned to a PCB ground that would act as a further shield for the FBP 22 and FBN 26 balls. The PGND balls 24, 28 are used in this example, but the staggered arrangement can contain signals other than PGND, for example, AVDD or others.

FIG. 4 illustrates a cross-sectional view across a portion of the line 4A-4A′ of FIG. 3, showing balls on copper pillars 42 on metal pads 40. A silicon active area 50 is shown underlying pads 40, which provide connections to the active circuits, not shown. Shown in the foreground in row E are balls FBP 22, extra ball 30, and ball 20b. In the background in row D are balls 20a, LXA 23, PGND 24, and 20c. The pitch is the distance between the midpoints of two adjacent balls. As shown in FIG. 4, the distance between the midpoints of balls PGND 24 and LXA 23 is the pitch. It can be seen that the foreground balls 30, 22, and 20b are offset by a half-pitch from the background balls 20a, 24, 23, and 20c in order to equalize distance. Only the row or column where the sensitive balls are located will be shifted. The entire row or column is shifted. As shown in the example, a portion of the row or column is shifted in one direction and the remainder of the row or column is shifted in the opposite direction around the noise-sensitive solder ball.

A pitch for the X dimension of the package (rows) could have a different pitch than for the Y dimension of the package (columns). From a staggering perspective, the shift in balls would be based on the pitch used in the noise-sensitive balls for which the mutual inductance is being equalized. That is, if a row of balls is being shifted, it is shifted by one-half the X-dimension pitch and if a column of balls is being shifted, it is shifted by one-half the Y-dimension pitch.

Switching converter simulations that include package parasitics show a significant reduction in the peak-to-peak noise induced into FBP-FBN when using the partially staggered ball arrangement of the present disclosure. Below is a table summarizing simulation results with a standard BGA package such as shown in FIG. 2 and with a partially staggered BGA package such as shown in FIG. 3.

TABLE 1

| | FBP-FBN pk-pk | PWM-CTRL |
|---|---|---|
| | noise (mV) | pk-pk noise (mV) |
| standard BGA package | 229 | 117 |
| partially staggered BGA | 151 | 100.6 |
| package | | |

The PWM control voltage, shown in the third column of Table 1, controls output voltage, current duty cycle, and jitter in a switching converter so a reduction of the noise on the PWM control voltage, as shown in the table above, is also beneficial and comes as a consequence of the reduction in FBP-FBN noise.

The present disclosure provides a BGA package with reduced noise and a method for making such a package. Localized staggering of the layout of balls that are associated with noise-sensitive signals will equalize parasitic mutual inductance and thus, reduce noise to those signals. The ball layout is shifted by half a pitch only in rows or columns in the localized area of the noise-sensitive signals to equalize the mutual inductance of signals. With the staggering or shifting of a row or rows (or column or columns) of balls, additional balls could be added for additional ground, if desired, but it is not necessary to add extra balls.

The package and process of the present disclosure can be used for other types of circuit and for any type of BGA package, with or without copper pillars, or other packages such as Wafer Level Chip Scale Packages (WLCSP).

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A ball grid array package comprising:
an array of solder balls mounted on a substrate wherein said solder balls provide package output
wherein solder balls adjacent to a noise-sensitive solder ball package output are shifted to equalize mutual parasitic inductance around said noise-sensitive solder ball package output.

2. The package according to claim 1 wherein said solder balls are mounted on copper pillars on metal pads on said substrate.

3. The package according to claim 1 wherein said solder balls are shifted by one-half the pitch of said array of solder balls.

4. The package according to claim 3 wherein one or more rows of solder balls is shifted.

5. The package according to claim 3 wherein one or more columns of solder balls is shifted.

6. The package according to claim 3 wherein one or more solder balls are shifted one-half pitch in one direction and one or more solder balls are shifted one-half pitch in an opposite direction.

7. The package according to claim 3 wherein an extra solder ball is added next to said noise-sensitive solder ball in an area provided by said shifting.

8. The package according to claim 7 wherein said extra solder ball is assigned to ground.

9. The package according to claim 1 wherein said array of solder balls has a first pitch in an X direction and a second pitch in a Y direction and wherein said solder balls are shifted by one-half of said first pitch if said solder balls are shifted in said X direction and wherein said solder balls are shifted by one-half of said second pitch if said solder balls are shifted in said Y direction.

10. A method of fabricating a ball grid array to reduce injected noise, comprising:
providing a plurality of solder balls on a substrate wherein said solder balls provide package output; and
designing an array layout of said plurality of solder balls wherein for each solder ball that is a noise-sensitive package output, shifting adjacent balls to said noise-sensitive solder ball so as to equalize mutual parasitic inductance around said noise-sensitive solder ball.

11. The method according to claim 10 further comprising mounting said plurality of solder balls on copper pillars formed on metal pads on said substrate.

12. The method according to claim 10 wherein said shifting is by one-half the pitch of said plurality of solder balls.

13. The method according to claim 10 wherein all solder balls in a row containing said noise-sensitive solder ball are shifted away from said noise-sensitive solder ball.

14. The method according to claim 10 wherein all solder balls in a column containing said noise-sensitive solder ball are shifted away from said noise-sensitive solder ball.

15. The method according to claim 10 wherein said array of solder balls has a first pitch in an X direction and a second pitch in a Y direction and wherein said solder balls are shifted by one-half of said first pitch if said solder balls are shifted in said X direction and wherein said solder balls are shifted by one-half of said second pitch if said solder balls are shifted in said Y direction.

16. The method according to claim 12 wherein said shifting by one-half pitch provides space to add an additional solder ball to said layout.

17. The method according to claim 16 wherein said additional solder ball is assigned to a ground to provide additional shielding to said noise-sensitive solder ball.

18. A package comprising:
an array of solder balls mounted on a substrate wherein said solder balls provide package output wherein solder balls adjacent to a noise-sensitive solder ball package output are shifted by one-half pitch of said array of solder balls to equalize mutual parasitic inductance around said noise-sensitive solder ball package output.

19. The package according to claim 18 wherein one or more of said solder balls are shifted in one direction along a row away from said noise-sensitive solder ball and one or more of said solder balls are shifted in an opposite direction along a row away from said noise-sensitive solder ball.

20. The package according to claim 18 wherein said solder balls are shifted in a direction along a column away from said noise-sensitive solder ball and one or more of said solder balls are shifted in an opposite direction along a column away from said noise-sensitive solder ball.

21. The package according to claim 18 wherein said array of solder balls has a first pitch in an X direction and a second pitch in a Y direction and wherein said solder balls are shifted by one-half of said first pitch if said solder balls are shifted in said X direction and wherein said solder balls are shifted by one-half of said second pitch if said solder balls are shifted in said Y direction.

22. The package according to claim 18 wherein an extra solder ball is added next to said noise-sensitive solder ball in an area provided by said shifting.

23. The package according to claim 22 wherein said extra solder ball is assigned to ground.
